(19) United States
(12) Patent Application Publication
(10) Pub. No.: US 2007/0025166 A1
(43) Pub. Date: Feb. 1, 2007

(54) Program/erase waveshaping control to increase data retention of a memory cell

(75) Inventors: Tzu-Ning Fang, Palo Alto, CA (US); Colin S. Bill, Cupertino, CA (US); Wei Daisy Cai, Fremont, CA (US); David Gaun, Brookline, MA (US); Eugen Gershon, San Jose, CA (US)

Correspondence Address: AMIN, TUROCY & CALVIN, LLP, 1900 EAST NINTH STREET, 24TH FLOOR, NATIONAL CITY CENTER, CLEVELAND, OH, 44114, US

(73) Assignee: SPANSION LLC, Sunnyvale, CA (US)

(21) Appl. No.: 11/191,126

(22) Filed: Jul. 27, 2005

(51) Int. Cl. G11C 29/00

(52) U.S. Cl. 365/201

(57) ABSTRACT

System(s) and method(s) of improving and controlling memory cell data retention are disclosed. A particular pulse width and magnitude is generated and applied to a memory cell made of at least two electrodes with a controllably conductive media between the at least two electrodes. The current across the memory cell is detected and a lower input pulse is sent to the memory cell. Application of the lower pulse controls the data retention of the memory cell without disturbing the final programming state of the memory cell.

### TECHNICAL FIELD

The invention generally relates to memory devices having controllably conductive layer(s) and methods of programming and using the memory devices. In particular, the invention relates to systems and methods for improving and controlling data retention of memory cells.

### BACKGROUND ART

The complexity, volume and use of computer and electronic devices has greatly increased the demand for memory cells and memory cell data retention. Digital cameras, digital audio players, personal digital assistants, and the like generally require large capacity memory cells (e.g., flash memory, smart media, compact flash, and the like). Memory cells are typically employed in various types of storage devices. These storage devices include long-term storage mediums including, for example, hard disk drives, compact disk drives and corresponding media, digital video disk (DVD) drives, and the like. The long-term storage mediums typically store large amounts of information at a low cost, but are slower than other types of storage devices. Storage devices also include memory devices which are often, but not always, short term storage mediums.

Memory devices can be subdivided into volatile and non-volatile types. Volatile memory cells generally lose their information in the event of power loss and typically require periodic refresh cycles to maintain their information. Volatile memory cells include, for example, random access memory (RAM), DRAM, SRAM and the like. Non-volatile memory cells maintain their information with or without maintaining power to the device. Examples of non-volatile memory cells include, for example, read only memory (ROM), programmable read only memory (PROM), erasable programmable read only memory (EPROM), electrically erasable programmable read only memory (EEPROM), flash EEPROM and the like. Compared to non-volatile memory cells, volatile memory cells generally provide faster operation at a lower cost. To retain the information, the stored data typically must be refreshed; that is, each capacitor must be periodically charged or discharged to maintain the capacitor's charged or discharged state. The maximum time allowable between refresh operations depends on the charge storage capabilities of the capacitors that form the memory cells in the array. A specified refresh time is generally provided by the memory device manufacturer to guarantee data retention in the memory cells.

Each memory cell in a memory device can be accessed or “read”, “written”, and “erased” with information. The memory cells maintain information in an “off” or an “on” state (e.g. are limited to 2 states), also referred to as “0” and “1”. Typically, a memory device is addressed to retrieve a specified number of byte(s) (e.g., 8 memory cells per byte). Such memory devices may be fabricated from semiconductor devices that perform these various functions and are capable of switching and maintaining the two states. The devices are often fabricated with inorganic solid state technology, such as, crystalline silicon devices. A common semiconductor device employed in memory devices is the metal oxide semiconductor field effect transistor (MOSFET).

Due to the escalating demand for information storage, memory device developers and manufacturers are constantly attempting to increase the data retention capability of memory devices. Concurrently, to achieve high storage densities, manufacturers typically focus on scaling down semiconductor device dimensions (e.g., at sub-micron levels). However, formation of various transistor type control devices typically required for programming memory cell arrays increases costs and reduces efficiency of circuit design.

Therefore, a need exists to overcome the aforementioned deficiencies associated with conventional devices.

### SUMMARY

The following is a summary of the invention in order to provide a basic understanding of some aspects of the invention. This summary is not intended to identify key/critical elements of the invention or to delineate the scope of the invention. Its sole purpose is to present some concepts of the invention in a simplified form as a prelude to the more detailed description that is presented later.

The invention relates to data retention and control of a memory device(s) containing at least one memory cell made of two electrodes with a controllably conductive media between the two electrodes, the controllably conductive media containing a low conductive layer and passive layer.

According to an aspect of the invention, a system for controlling data retention in a memory device is provided. The memory device has a memory storage medium containing a controllably conductive media between a first electrode and a second electrode. The system has a first component that provides a programming signal to the memory device and a second component that provides information to the first component based, at least in part, upon information associated with a measured current through the memory device. The second component controls an output, a programming signal, a pulse magnitude and/or a pulse width of the first component. The second component also provides information indicating the measured current surpassed a current level or range.

Yet another aspect of the invention is a method of controlling data retention of a memory device involving providing a memory cell having a memory storage medium with a controllably conductive media between a first electrode and a second electrode, applying a programming signal to the memory device and measuring the current through the memory cell. The method further involves monitoring the measured current to determine when the measured current reaches or exceeds a threshold current level. The method may further involve adjusting the programming signal based upon the monitored current level.

Still another aspect of the invention is a system for controlling data in a memory cell comprising a means for providing an input signal, a means for monitoring the programming state and a means for controlling the input signal based upon the programming state.

To the accomplishment of the foregoing and related ends, the invention comprises the features hereinafter fully described and particularly pointed out in the claims. The following description and the annexed drawings set forth in detail certain illustrative aspects and implementations of the invention. These are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF DRAWINGS

FIG. 1 illustrates a flow diagram illustrating a method of program/erase wave shaping and data retention control according to an aspect of the invention.

FIG. 2 illustrates a block diagram of an exemplary system employing a memory device in accordance with an aspect of the invention.

FIG. 3 illustrates an exemplary pulse waveform in accordance with an aspect of the invention.

FIG. 4 illustrates an exemplary pulse waveform in accordance with an aspect of the invention.

FIG. 5 illustrates a graph related to a program operation applied to a memory cell in accordance with an aspect of the invention.

FIG. 6 illustrates an exemplary test system in accordance with an aspect of the invention.

FIG. 7 illustrates a detailed block diagram of an exemplary test system in accordance with an aspect of the invention.

FIG. 8 illustrates a diagram of exemplary general software components of a test system in accordance with an aspect of the invention.

FIG. 9 illustrates a perspective view of a two dimensional microelectronic device containing a plurality of memory cells in accordance with an aspect of the invention.

FIG. 10 illustrates a perspective view of a three dimensional microelectronic device containing a plurality of memory cells in accordance with another aspect of the invention.

FIG. 11 illustrates representative computing and operational environments in accordance with the invention.

### DETAILED DESCRIPTION

The invention is now described with reference to the drawings, wherein like reference numerals are used to refer to like elements throughout. In the following description, for purposes of explanation, numerous specific details are set forth in order to provide a thorough understanding of the invention. It may be evident, however, that the invention may be practiced without these specific details. In other instances, well-known structures and devices are shown in block diagram form in order to facilitate describing the invention.

This invention involves improving data retention of a memory cell by controlling the program and erase wave shapes of memory cells containing at least two electrodes, as one or more electrode may be deposited between the two electrodes that sandwich a controllably conductive media. The electrodes are made of conductive material, such as conductive metal, conductive metal alloys, conductive metal oxides, conductive polymer films, semiconductor materials, and the like. Typically, the thickness of each electrode is independently about 0.01 μm or more and about 10 μm or less.

The controllably conductive media, disposed between the two electrodes, can be rendered conductive, semiconductive, or nonconductive in a controllable manner using an external stimuli. Generally, in the absence of an external stimuli, the controllably conductive media is nonconductive or has a high impedance. Further, in some embodiments, multiple degrees of conductivity/resistivity may be established for the controllably conductive media in a controllable manner. For example, the multiple degrees of conductivity/resistivity for the controllably conductive media may include a nonconductive state, a highly conductive state, and a semiconductive state. The controllably conductive media can be rendered conductive, non-conductive or any state therebetween (degree of conductivity) in a controllable manner by an external stimulus (external meaning originating from outside the controllably conductive media). For example, under an external electric field, radiation, and the like, a given nonconductive controllably conductive media is converted to a conductive controllably conductive media.

The controllably conductive media contains one or more low conductive layers and one or more passive layers. The low conductive layer can be formed from various materials including organic semiconductor materials, inorganic semiconductor materials and mixtures of organic and inorganic semiconductor materials. Typically, the low conductive layer has a thickness of about 0.001 μm or more and about 5 μm or less.

The organic semiconductor layer contains at least one of an organic polymer (such as a conjugated organic polymer), an organometallic compound (such as a conjugated organometallic compound), an organometallic polymer (such as a conjugated organometallic polymer), a buckyball, a carbon nanotube (such as a C6-C60 carbon nanotubes), and the like. The organic polymers (or the organic monomers constituting the organic polymers) may be cyclic or acyclic. During formation or deposition, the organic polymer self assembles between the electrodes. Examples of conjugated organic polymers include one or more of polyacetylene; polyphenylacetylene; polydiphenylacetylene; polyaniline; poly(p-phenylene vinylene); polythiophene; polyporphyrins; porphyrinic macrocycles, thiol derivatized polyporphyrins; polymetallocenes such as polyferrocenes, polyphthalocyanines; polyvinylenes; polystiroles; poly(t-butyl)diphenylacetylene; poly(trifluoromethyl)diphenylacetylene; polybis(trifluoromethyl)acetylene; polybis(t-butyldiphenyl)acetylene; poly(trimethylsilyl) diphenylacetylene; poly(carbazole)diphenylacetylene; polydiacetylene; polypyridineacetylene; polymethoxyphenylacetylene; polymethylphenylacetylene; poly(t-butyl)phenylacetylene; polynitro-phenylacetylene; poly(trifluoromethyl) phenylacetylene; poly(trimethylsilyl)pheylacetylene; polydipyrrylmethane; polyindoqiunone; polydihydroxyindole; polytrihydroxyindole; furane-polydihydroxyindole; polyindoqiunone-2-carboxyl; polyindoqiunone; polybenzobisthiazole; poly(p-phenylene sulfide); polypyrrole; polystyrene; polyfuran; polyindole; polyazulene; polyphenylene; polypyridine; polybipyridine; polysexithiofene; poly(siliconoxohemiporphyrazine); poly(germaniumoxohemiporphyrazine); poly(ethylenedioxythiophene); polypyridine metal complexes; and the like.

Inorganic materials include transition metal sulfides, chalcogenides, and transition metal oxides. Examples include copper oxide (CuO, Cu₂O), iron oxide (FeO, Fe₃O₄), manganese oxide (MnO₂, Mn₂O₃, etc), titanium oxide (TiO₂).

The active low conductive layer can be a mixture of organic and inorganic materials. The inorganic material (transition metal oxide/sulfide) is usually embedded in an organic semiconductor material. Examples include polyphenylacetylene mixed with Cu₂S, polyphenylacetylene mixed with Cu₂O, and the like.

The passive layer contains at least one conductivity facilitating compound that contributes to the controllably conductive properties of the controllably conductive media. The conductivity facilitating compound has the ability to donate and accept charges (holes and/or electrons). The passive layer thus may transport between an electrode and the low conductive layer/passive layer interface, facilitate charge/carrier injection into the low conductive layer, and/or increase the concentration of a charge carrier in the low conductive layer. Examples of conductivity facilitating compounds that may make up the passive layer include one or more of copper sulfide (CuₓS, where x is from about 0.5 to about 3), silver sulfide (Ag₂S, AgS), gold sulfide (Au₂S, AuS), and the like. Typically, the passive layer containing the conductivity facilitating compound has a thickness of about 2 Å or more and about 0.1 μm or less.

The impedance of the controllably conductive media changes when an external stimuli, such as an applied electric field is imposed. A plurality of the memory cells, which may be referred to as an array, form, with other components, a memory device. The programming and erase of the memory cell is very sensitive to the applied pulse shape. Using equipment to generate different pulse types and by monitoring the current, a lower pulse may be sent to the memory device during or after cell switching. In this way, the pulse is used to control the data retention of the memory device without disturbing the final programming state.

While, for purposes of simplicity of explanation, the one or more methodologies shown herein, e.g., in the form of a flow chart, are shown and described as a series of acts, it is to be understood and appreciated that the invention is not limited by the order of acts, as some acts may, in accordance with the invention, occur in a different order and/or concurrently with other acts from that shown and described herein. For example, those skilled in the art will understand and appreciate that a methodology may alternatively be represented as a series of interrelated states or events, such as in a state diagram. Moreover, not all illustrated acts may be required to implement a methodology in accordance with the invention.

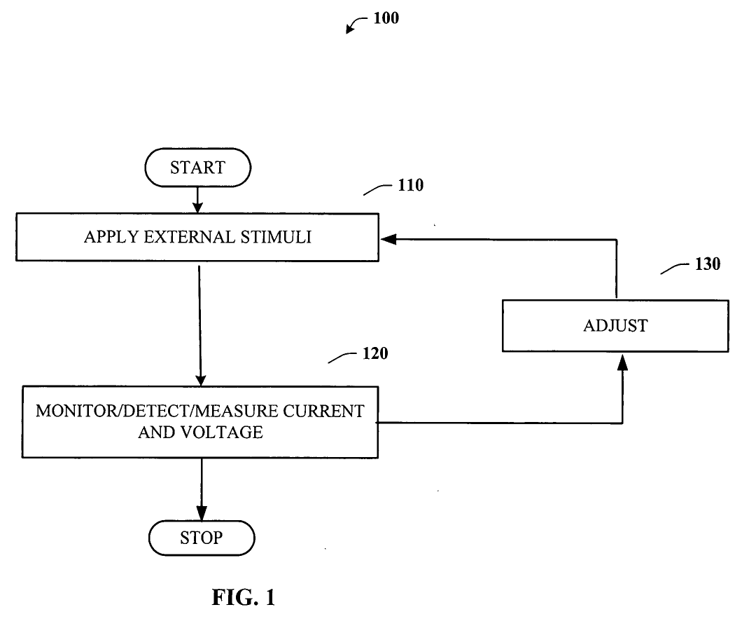

FIG. 1 is a flowchart illustrating a methodology 100 according to one aspect of the invention. At 110 an external stimuli, such as an applied electric field, is applied to a memory cell having a controllably conductive media (external meaning originating from outside the controllably conductive media). The external stimuli may be, for example, a programming signal, an erase signal, or a read signal. Operation of memory devices/cells is facilitated using an external stimuli to achieve a switching effect. The external stimuli applied may be in the form of a variety of wave shapes. For example, a mixed read/program/erase pulse may be applied. This pulse may alternate between a program/erase pulse and a read pulse. Another waveform that can be applied, for example, is a staircase waveform with a pulse magnitude that is increased in incremental steps rather than at a constant rate. However, various other waveforms may be utilized as an external stimuli.

The external stimuli may be applied via any system known in the art. For example, the system may be a tester that includes an arbitrary waveform generator (AWG) and a data acquisition system. The AWG may include a waveform generator capable of outputting a waveform based upon initial configuration parameters and which is capable of changing those parameters dynamically as the process continues. However, it is contemplated that any system capable of applying an external stimuli, in the form of a waveform, and controlling the waveform output based on the state of a memory cell may be utilized with this invention.

As the external stimuli is applied to the memory cell, the voltage across and current through the memory cell increases, indicating the cell is switching. This increase in current and voltage is due to the impedance of the controllably conductive media changing when the external stimuli is imposed. Under various conditions, the memory cell is either conductive (low impedance or “on” state) or non-conductive (high impedance or “off” state).

The memory cell may further have more than one conductive or low impedance state, such as a very high conductive state (very low impedance state), a highly conductive state (low impedance state), a conductive state (medium level impedance state), and a non-conductive state (high impedance state) thereby enabling the storage of multiple bits of information in a single memory cell, such as 2 or more bits of information or 4 or more bits of information.

The increase in voltage and current indicates the cell has switched to a programming state, for example. Switching a memory device to a particular state is referred to as programming or writing. Programming is accomplished by applying a particular voltage (e.g., 9 volts, 2 volts, 1 volt, . . . ) across a selectively conductive media via electrodes. The particular voltage, also referred to as a threshold voltage, varies according to a respective desired state and is generally substantially greater than voltages employed during normal operation of the memory device. Thus, there is typically a separate threshold voltage that corresponds to respective desired states (e.g., “off”, “on”, “write” etc.).

Switching the memory cell to the “on” state from the “off” state occurs when an external stimuli exceeds a threshold value. Switching the memory cell to the “off” state from the “on” state occurs when an external stimuli does not exceed a threshold value or does not exist. The threshold value varies depending upon a number of factors including the identity of the materials that constitute the memory cell, the low conductive layer, and the passive layer, the thickness of the various layers, and the like. Thus, the threshold voltage to achieve each state may be predetermined based on the characteristics of the memory cell.

Generally speaking, the presence of an external stimuli such as an applied electric field that exceeds a threshold value (“on” state) permits an applied voltage to write or erase information into/from the memory cell and the presence of an external stimuli such as an applied electric field that is less than a threshold value permits an applied voltage to read information from the memory cell; whereas the absence of the external stimuli that exceeds a threshold value (“off” state) prevents an applied voltage to write or erase information into/from the memory cell.

To write information into the memory cell, a voltage or pulse signal that exceeds the threshold is applied. To read information written into the memory cell, a voltage or electric field of any polarity is applied. To erase information written into the memory cell, a negative voltage or a polarity opposite the polarity of the writing signal that exceeds a threshold value is applied.

With continuing reference to FIG. 1, at 120 a controller monitors and/or measures the current and voltage level of the memory cell. Once cell switching begins, the controller detects whether a pre-selected threshold value or current level or current range has been surpassed. The measured current and voltage levels may be used for comparison with data retention information to determine if the current is at the proper level to maximize the level of data retention in the memory cell. The controller may also monitor the current and upon cell switching, the detector may indicate the current, and input stimuli, needs to be adjusted in order to maximize the data retention capabilities of the memory cell. For example, the input stimuli may be adjusted to provide a lower pulse magnitude and/or to control the pulse width. In this way, the external stimuli, or pulse is used to control the data retention without disturbing the final programming state.

At 130, the controller and/or test system may adjust the input stimuli, for example, the controller may decrease or otherwise change the pulse magnitude and width of an external stimuli based upon information obtained regarding current levels and whether the threshold level has been reached or surpassed. When the current exceeds a threshold or current level, indicating programming, a smaller magnitude pulse with a defined pulse width may be applied via an external stimuli to the memory cell to control data retention levels. Based on the pulse magnitude and width, the cell data retention is controlled without disturbing the final programming state of the memory cell.

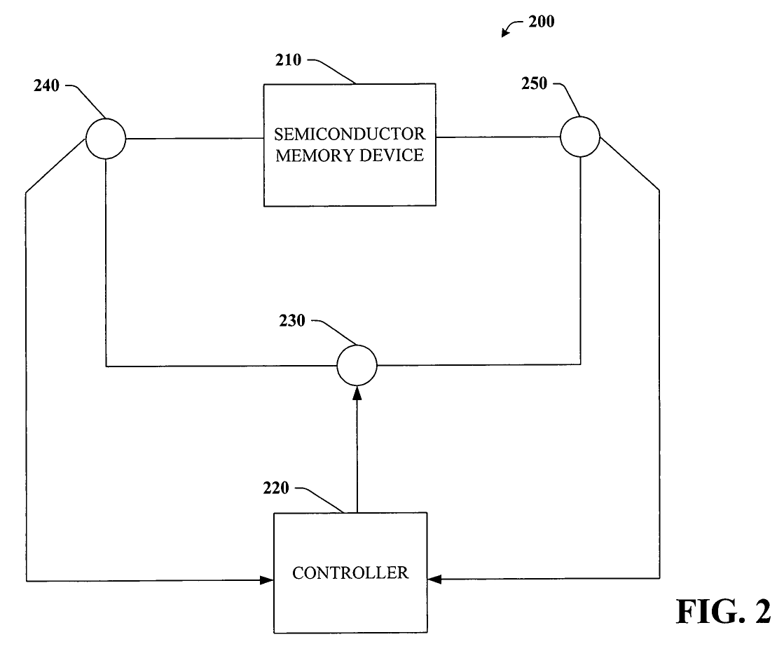

Referring to FIG. 2, an exemplary system 200 for programming a memory device 210 in accordance with an aspect of the invention is illustrated. The system 200 includes a memory device 210, a controller 220 and a programming signal source 230. The system 200 further includes a first measurement device 240 and may include a second measurement device 250, however, it is contemplated that one device may perform the functions of the first and second measurement devices 240, 250. By utilizing information associated with a current across the memory device 210, the system 200 can more effectively and efficiently program the memory device 210 and provide greater data retention.

The controller 220 provides information to the programming signal source 230 based, at least in part, upon information associated with a current measurement of the semiconductor memory device 210. For example, the information associated with the current across the memory device 210 can be received from a measurement device(s) 240 and 250 (e.g., an amp meter).

By determining the current of the memory device 210, the controller 220 can determine a programming state of the memory device 210. Based, at least in part, upon information associated with the current of the memory device 210, the controller 220 can provide information to the programming signal source 230. For example, based on the current of the memory device 210, the controller 220 can determine a suitable voltage and/or pulse width required to place the memory device 210 into a desired state.

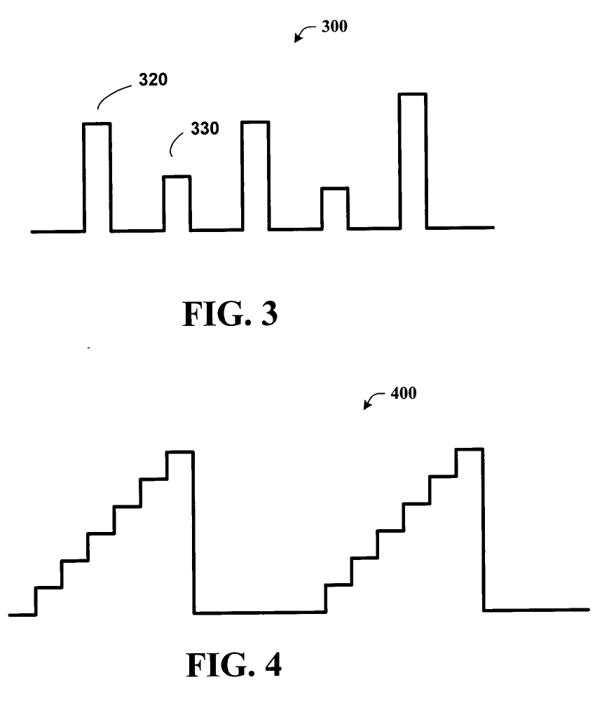

The programming signal source 230 generates a waveform, which is applied to the memory cell 210. The pulse generated may be any number of types or shapes. For example, as depicted in FIG. 3, the shape 300 generated may be a mixture of pulses, such as a programming/erase pulse 320 integrated with a read pulse 330. In this fashion, the memory cell is alternating between a program/erase state and a read state. As indicated in FIG. 4, another pulse type generated may be a staircase waveform 400. The staircase pulse applies voltage across the memory device as stepped increases of voltage rather than a constantly increasing voltage rate. A staircase waveform 400 provides gentler or smoother programming while allowing better control of the final programming state of the memory device. While only two different types of waveforms are shown, it is understood that a wide variety of waveforms can be used to program, erase and read the memory cell and all such waveforms are contemplated within the scope of this invention.

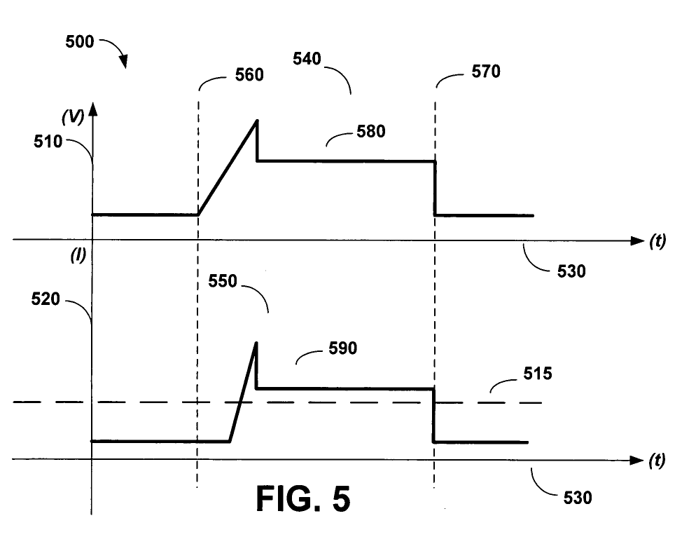

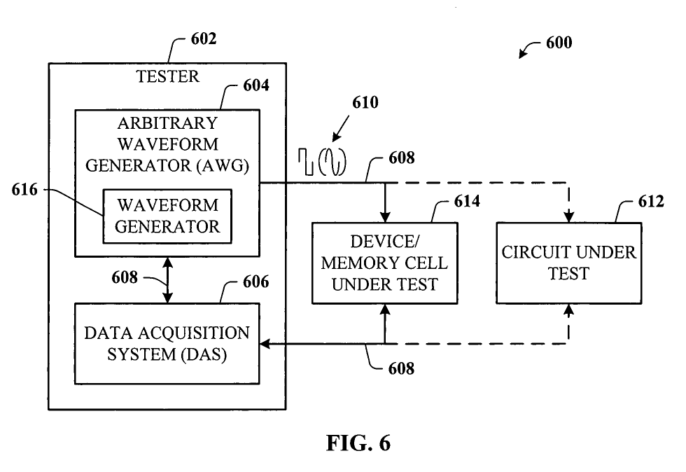

Referring now to FIG. 5, a graph 500 illustrates the voltage across and the current through a memory device. The graph 500 displays a vertical axis with an upper portion representing voltage, V, 510, and a lower portion representing current, I, 520. The graph 500 further includes a horizontal t axis 530 to represent a recorded duration of time. Plotted graph 540 represents the measured voltage level applied to a memory cell during a programming operation and plotted graph 550 represents the measured current level associated with the same program operation.

Vertical line 560 represents the period when programming begins and the cell is switching to a lower resistance state. At 560, the voltage begins to increase and the current increases thereafter. Horizontal line 515 is the current threshold value. Once the current meets or exceeds this pre-defined minimum threshold value, the memory cell switches into the program state. The controller detects this increase in current and sends a lower external pulse to the memory device causing the voltage level 580 and current level 590 to decrease. A smaller voltage reduces the current stress after programming which enhances data retention without overstressing the cell with high current. While FIG. 5 shows the current level 590 maintained above the threshold value 515, it is not necessary to maintain a level above or at the threshold value 515 and the current level 590 may even fall below the threshold value 515 at this stage. During the period of lower voltage and current levels 580, 590, the lower pulse sent to the memory device results in controlled data retention without disturbing the final programming state.

With reference to FIG. 6, there is illustrated an exemplary test system 600 that may be utilized as a programming source and a controller. The test system 600 contains a tester 602 that includes an arbitrary waveform generator (AWG) 604 and a data acquisition system (DAS) 606 connected through a feedback loop 608 that enables the AWG 604 to change its output waveform 610 on-the-fly based on the status of a circuit under test 612 or device under test 614, such as a memory cell, that is being monitored by the DAS 606. The AWG 604 includes a waveform generator 616 that outputs the waveform 610 in accordance with initial configuration parameters, which initial parameters can then be adjusted dynamically as the test on the device proceeds. As the waveform 610 is imposed on the memory cell, the DAS 606 monitors one or more parameters of the memory cell. For example, the memory cell could manifest a certain current or voltage (or other parameter or combination of parameters) that requires a change in the waveform 610. For example, when the memory cell current reaches and/or exceeds a threshold level indicating that the memory cell is in the programming state, a change resulting in a reduced current across the memory cell may be desired. The feedback architecture facilitates a number of changes in the output waveform 610, including a change in the magnitude, shape or pulse width of the output waveform 610. The system tester 602 is built as a combination of fast analog and digital circuits, programmable logic for user interface and settings, and waveform memory (on both the AWG 604 and DAS 606). Fast ADC (analog-to-digital converter) devices and DAC (digital-to-analog converter) devices allow speeds up to one giga-samples per second (Gsps) using existing off-the-shelf components.

The test system 600 can be applied to any equipment, device, or circuit that is chosen to be tested, even to consumer-level devices. Particularly, the system can be used to characterize polymer cell electrical behavior and be the basic tool for model generation. The tester is designed to drive the cell into “programmed” and “erased” states while monitoring the current through the cell and voltage across it. The tester may also record the data for further processing.

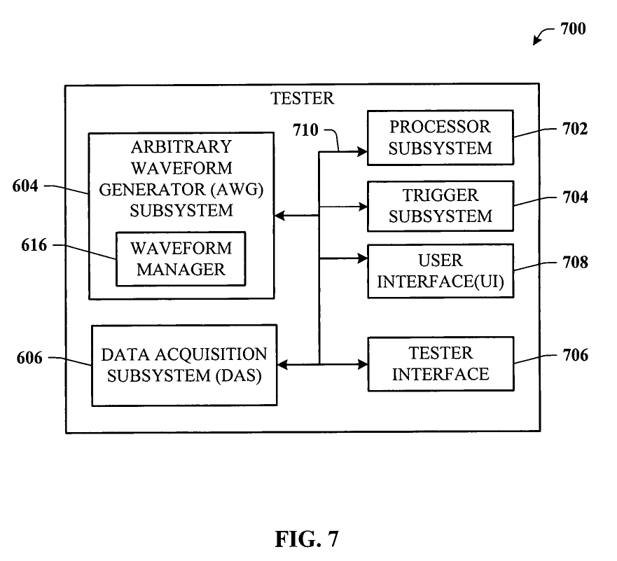

Referring now to FIG. 7, there is illustrated a more detailed block diagram of an exemplary tester 700. The tester 700 includes the AWG subsystem 604 to control output of the waveform, the waveform manager subsystem 616 that processes the waveform according to changed memory cell parameters, the DAS subsystem 606 that connects to the memory cell to receive parameter signals during the test operation, a processor subsystem 702 that facilitates control and interaction of tester subsystems, a trigger system 704 that facilitates event triggering, and a tester interface 706 that provides the hardware communication and data connections to the memory cell. The tester 700 can also include a user interface (UI) subsystem 708 that facilitates visual and user interaction therewith. The UI 708 can be an LCD monitor, a plasma monitor, or any suitable display, for example. Each of the subsystems (604, 606, 702, 704, 706, and 708) is interconnected by an internal communication bus 710, according to conventional communication schemes. Note that the UI 708 can be an external monitor that interfaces to the tester 700 via the tester interface 706 for providing a means of perceiving data and control information of the tester subsystems. The tester interface 706 can also accommodate user input devices, such as a wired/wireless keyboard, mouse, trackball, etc., to allow the user to interact therewith.

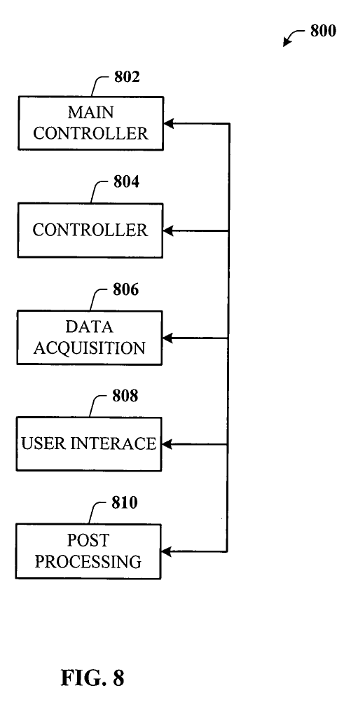

Referring now to FIG. 8, there is illustrated a diagram of the general software components 800 of an exemplary tester system according to an aspect of the invention. A main controller software module 802 executes with the waveform manager 616 (of FIG. 7) to facilitate control of at least the inputs and outputs of the DAS, the UI, and AWG. Where an external computer (not shown) is used to interface to the tester, the main controller software 802 also interfaces thereto for the communication management of signals and data. There is provided a controller software module 804 the functions of which can be combined with the main controller module 802. However, it can be advantageous to separate the functions for efficiency and bandwidth purposes. For example, the main controller module 802 can be tasked with managing interaction between the other modules, while the controller 804 can be dedicated for more specific tasks related to waveform slicing, generation, and control. The controller 804 can manage tester-computer communications, UI parameters, initialization, activation, statusing, and data handling, for example. In one implementation, the controller module 804 is hosted in an external computer that communicates with the tester.

The software components 800 also include a data acquisition software module 806 that manages data acquisition and data communication of the DAS. Where the tester interfaces to an external computer, the data acquisition module can also communicate the data to the computer for processing and presentation. A UI software module 808 facilitates inputting, presenting, and viewing of the tester information, such as data and signals, for example. The user can input system parameters, test parameters, control the application operating mode, repetition rate, waveform parameters, cause the output of parameters, initiate waveform generation instructions to tester circuitry, manage the DAS data format and, perform verification and acknowledgements, to name just a few. A post-processing software module 810 performs processing of the data and signals received by the DAS during testing of the memory cell, such as the application of mathematical algorithms on the data. It is to be appreciated, however, that the post processing module 810 can also be used to process initial configuration data (e.g., calibration) before the test begins, or any data acquired from initial setup to final results of the test process after the testing has completed.

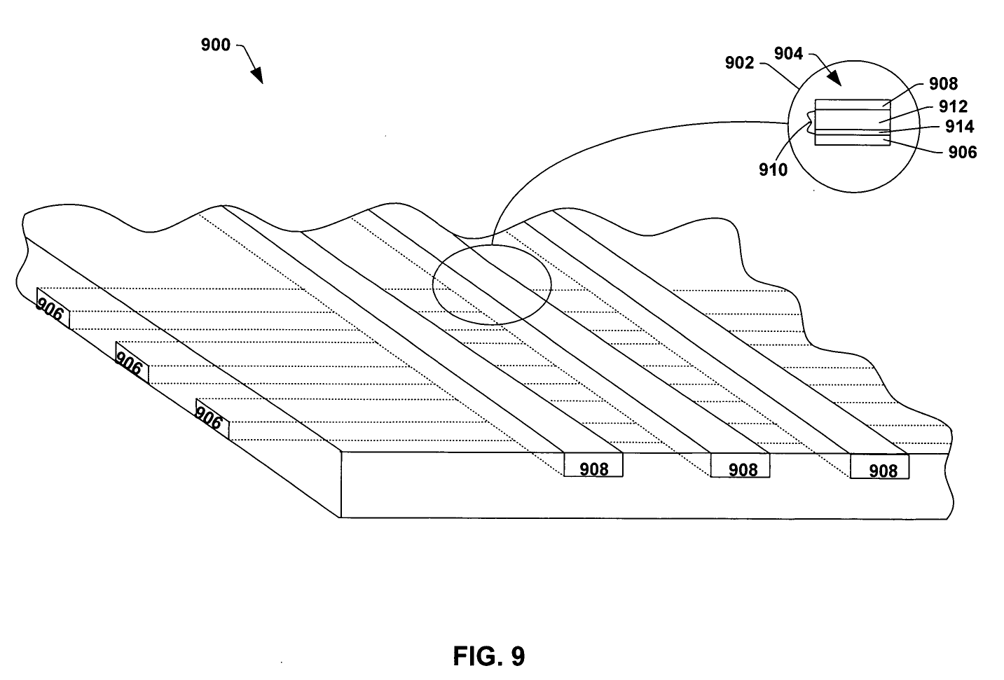

Referring now to FIG. 9, a brief description of an exemplary microelectronic memory device 900 containing a plurality of memory cells that can be utilized in accordance with an aspect of the invention is shown, as well as an exploded view 902 of an exemplary memory cell 904. The microelectronic memory device 900, for example, contains a desired number of memory cells, as determined by the number of rows, columns, and layers (three dimensional orientation described later) present. The first electrodes 906 and the second electrodes 908 are shown in substantially perpendicular orientation, although other orientations are possible to achieve the structure of the exploded view 902. Each memory cell 904 contains a first electrode 906 and a second electrode 908 with a controllably conductive media 910 therebetween. The controllably conductive media 910 contains a low conductive layer 912 and passive layer 914. Peripheral circuitry and devices are not shown for brevity.

The memory cells contain at least two electrodes, as one or more electrodes may be disposed between the two electrodes that sandwich the controllably conductive media. The electrodes are made of conductive material, such as conductive metal, conductive metal alloys, conductive metal oxides, conductive polymer films, semiconductive materials, and the like.

Examples of electrodes include one or more of aluminum, chromium, copper, germanium, gold, magnesium, manganese, indium, iron, nickel, palladium, platinum, silver, titanium, zinc, and alloys thereof; indium-tin oxide (ITO); polysilicon; doped amorphous silicon; metal silicides; and the like. Alloy electrodes specifically include Hastelloy®, Kovar®, Invar, Monel®, Inconel®, brass, stainless steel, magnesium-silver alloy, and various other alloys.

The controllably conductive media, disposed between the two electrodes, can be rendered conductive, semiconductive, or nonconductive in a controllable manner using an external stimuli. Generally, in the absence of an external stimuli, the controllably conductive media is nonconductive or has a high impedance. Further, in some embodiments, multiple degrees of conductivity/resistivity may be established for the controllably conductive media in a controllable manner. For example, the multiple degrees of conductivity/resistivity for the controllably conductive media may include a nonconductive state, a highly conductive state, and a semiconductive state.

The controllably conductive media can be rendered conductive, non-conductive or any state therebetween (degree of conductivity) in a controllable manner by an external stimulus (external meaning originating from outside the controllably conductive media). For example, under an external electric field, radiation, and the like, a given nonconductive controllably conductive media is converted to a conductive controllably conductive media.

The controllably conductive media contains one or more low conductive layers and one or more passive layers. In one embodiment, the controllably conductive media contains at least one organic semiconductor layer that is adjacent a passive layer (without any intermediary layers between the organic semiconductor layer and passive layer). In another embodiment, the controllably conductive media contains at least one inorganic low conductive layer that is adjacent a passive layer (without any intermediary layers between the inorganic layer and passive layer). In yet another embodiment, the controllably conductive media contains a mixture of organic and inorganic materials as the low conductive layer that is adjacent a passive layer (without any intermediary layers between the low conductive layer and passive layer).

The memory devices described herein can be employed to form logic devices such as central processing units (CPUs); volatile memory devices such as DRAM devices, SRAM devices, and the like; input/output devices (I/O chips); and non-volatile memory devices such as EEPROMs, EPROMs, PROMs, and the like. The memory devices may be fabricated in planar orientation (two dimensional) or three dimensional orientation containing at least two planar arrays of the memory cells.

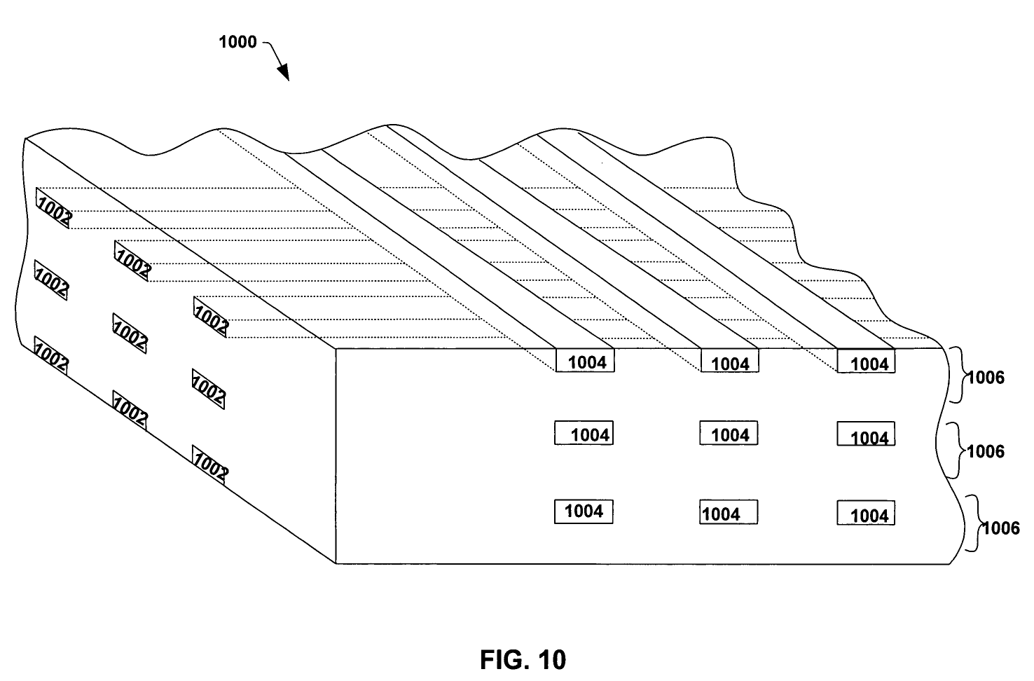

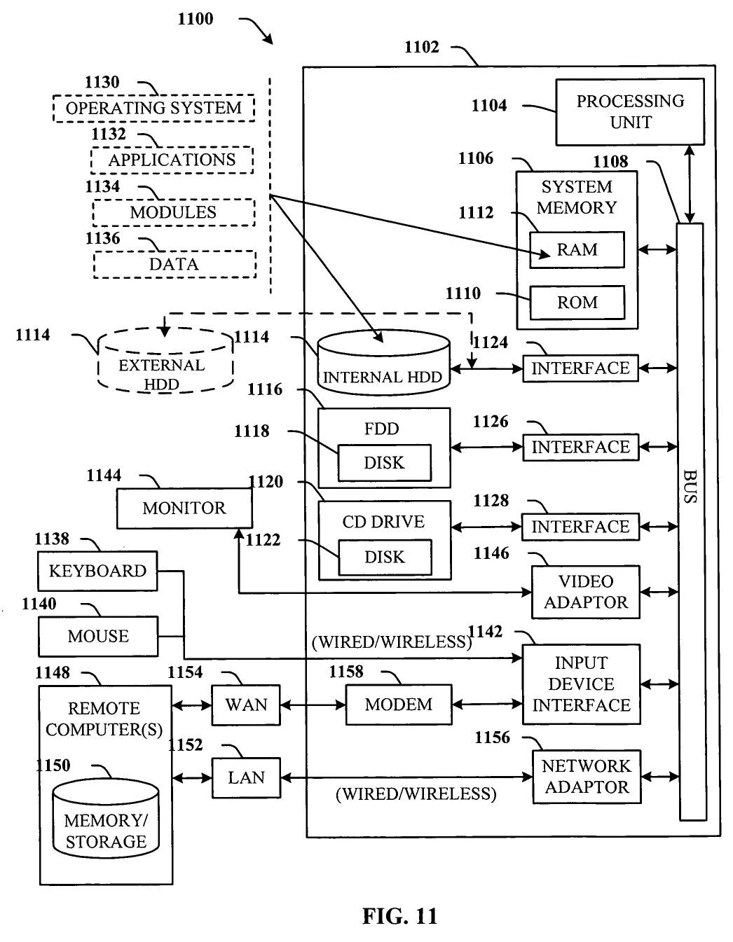

Referring to FIG. 10, an exemplary three dimensional microelectronic memory device 1000 containing a plurality of memory cells that can be utilized in accordance with an aspect of the invention is shown. The three dimensional microelectronic memory device 1000 contains a plurality of first electrodes 1002, a plurality of second electrodes 1004, and a plurality of memory cell layers 1006. Between the respective first and second electrodes are the controllably conductive media (not shown). The plurality of first electrodes 1002 and the plurality of second electrodes 1004 are shown in substantially perpendicular orientation, although other orientations are possible. The three dimensional microelectronic memory device is capable of containing an extremely high number of memory cells thereby improving device density. Peripheral circuitry and devices are not shown for brevity.

The memory cells/devices are useful in any device requiring memory. For example, the memory devices are useful in computers, appliances, industrial equipment, hand-held devices, telecommunications equipment, medical equipment, research and development equipment, transportation vehicles, radar/satellite devices, and the like. Hand-held devices, and particularly hand-held electronic devices, achieve improvements in portability due to the small size and light weight of the new memory devices. Examples of hand-held devices include cell phones and other two way communication devices, personal data assistants, palm pilots, pagers, notebook computers, remote controls, recorders (video and audio), radios, small televisions and web viewers, cameras, and the like.

Referring now to FIG. 11, there is illustrated a block diagram of a computer operable to execute the disclosed architecture. In order to provide additional context for various aspects of the invention, FIG. 11 and the following discussion are intended to provide a brief, general description of a suitable computing environment 1100 in which the various aspects of the invention may be implemented. While the invention has been described above in the general context of computer-executable instructions that may run on one or more computers, those skilled in the art will recognize that the invention also may be implemented in combination with other program modules and/or as a combination of hardware and software.

Generally, program modules include routines, programs, components, data structures, etc., that perform particular tasks or implement particular abstract data types. Moreover, those skilled in the art will appreciate that the inventive methods may be practiced with other computer system configurations, including single-processor or multiprocessor computer systems, minicomputers, mainframe computers, as well as personal computers, hand-held computing devices, microprocessor-based or programmable consumer electronics, and the like, each of which may be operatively coupled to one or more associated devices.

The illustrated aspects of the invention may also be practiced in distributed computing environments where certain tasks are performed by remote processing devices that are linked through a communications network. In a distributed computing environment, program modules may be located in both local and remote memory storage devices.

A computer typically includes a variety of computer-readable media. Computer-readable media can be any available media that can be accessed by the computer and includes both volatile and nonvolatile media, removable and non-removable media. By way of example, and not limitation, computer readable media can include computer storage media and communication media. Computer storage media includes both volatile and nonvolatile, removable and non-removable media implemented in any method or technology for storage of information such as computer readable instructions, data structures, program modules or other data. Computer storage media includes, but is not limited to, RAM, ROM, EEPROM, flash memory or other memory technology, CD-ROM, digital video disk (DVD) or other optical disk storage, magnetic cassettes, magnetic tape, magnetic disk storage or other magnetic storage devices, or any other medium which can be used to store the desired information and which can be accessed by the computer.

Communication media typically embodies computer-readable instructions, data structures, program modules or other data in a modulated data signal such as a carrier wave or other transport mechanism, and includes any information delivery media. The term “modulated data signal” means a signal that has one or more of its characteristics set or changed in such a manner as to encode information in the signal. By way of example, and not limitation, communication media includes wired media such as a wired network or direct-wired connection, and wireless media such as acoustic, RF, infrared and other wireless media. Combinations of the any of the above should also be included within the scope of computer-readable media.

With reference again to FIG. 11, there is illustrated an exemplary environment 1100 for implementing various aspects of the invention that includes a computer 1102, the computer 1102 including a processing unit 1104, a system memory 1106 and a system bus 1108. The system bus 1108 couples system components including, but not limited to, the system memory 1106 to the processing unit 1104. The processing unit 1104 may be any of various commercially available processors. Dual microprocessors and other multi-processor architectures may also be employed as the processing unit 1104.

The system bus 1108 can be any of several types of bus structure that may further interconnect to a memory bus (with or without a memory controller), a peripheral bus, and a local bus using any of a variety of commercially available bus architectures. The system memory 1106 includes read only memory (ROM) 1110 and random access memory (RAM) 1112. A basic input/output system (BIOS) is stored in a non-volatile memory 1110 such as ROM, EPROM, EEPROM, which BIOS contains the basic routines that help to transfer information between elements within the computer 1102, such as during start-up. The RAM 1112 can also include a high-speed RAM such as static RAM for caching data.

The computer 1102 further includes an internal hard disk drive (HDD) 1114 (e.g., EIDE, SATA), which internal hard disk drive 1114 may also be configured for external use in a suitable chassis (not shown), a magnetic floppy disk drive (FDD) 1116, (e.g., to read from or write to a removable diskette 1118) and an optical disk drive 1120, (e.g., reading a CD-ROM disk 1122 or, to read from or write to other high capacity optical media such as the DVD). The hard disk drive 1114, magnetic disk drive 1116 and optical disk drive 1120 can be connected to the system bus 1108 by a hard disk drive interface 1124, a magnetic disk drive interface 1126 and an optical drive interface 1128, respectively. The interface 1124 for external drive implementations includes at least one or both of Universal Serial Bus (USB) and IEEE 1394 interface technologies.

The drives and their associated computer-readable media provide nonvolatile storage of data, data structures, computer-executable instructions, and so forth. For the computer 1102, the drives and media accommodate the storage of any data in a suitable digital format. Although the description of computer-readable media above refers to a HDD, a removable magnetic diskette, and a removable optical media such as a CD or DVD, it should be appreciated by those skilled in the art that other types of media which are readable by a computer, such as zip drives, magnetic cassettes, flash memory cards, cartridges, and the like, may also be used in the exemplary operating environment, and further, that any such media may contain computer-executable instructions for performing the methods of the invention.

A number of program modules can be stored in the drives and RAM 1112, including an operating system 1130, one or more application programs 1132, other program modules 1134 and program data 1136. All or portions of the operating system, applications, modules, and/or data can also be cached in the RAM 1112.

It is appreciated that the invention can be implemented with various commercially available operating systems or combinations of operating systems.

A user can enter commands and information into the computer 1102 through one or more wired/wireless input devices, e.g., a keyboard 1138 and a pointing device, such as a mouse 1140. Other input devices (not shown) may include a microphone, an IR remote control, a joystick, a game pad, a stylus pen, touch screen, or the like. These and other input devices are often connected to the processing unit 1104 through an input device interface 1142 that is coupled to the system bus 1108, but may be connected by other interfaces, such as a parallel port, an IEEE 1394 serial port, a game port, a USB port, an IR interface, etc.

A monitor 1144 or other type of display device is also connected to the system bus 1108 via an interface, such as a video adapter 1146. In addition to the monitor 1144, a computer typically includes other peripheral output devices (not shown), such as speakers, printers etc.

The computer 1102 may operate in a networked environment using logical connections via wired and/or wireless communications to one or more remote computers, such as a remote computer(s) 1148. The remote computer(s) 1148 may be a workstation, a server computer, a router, a personal computer, portable computer, microprocessor-based entertainment appliance, a peer device or other common network node, and typically includes many or all of the elements described relative to the computer 1102, although, for purposes of brevity, only a memory storage device 1150 is illustrated. The logical connections depicted include wired/wireless connectivity to a local area network (LAN) 1152 and/or larger networks, e.g., a wide area network (WAN) 1154. Such LAN and WAN networking environments are commonplace in offices, and companies, and facilitate enterprise-wide computer networks, such as intranets, all of which may connect to a global communication network, e.g., the Internet.

When used in a LAN networking environment, the computer 1102 is connected to the local network 1152 through a wired and/or wireless communication network interface or adapter 1156. The adaptor 1156 may facilitate wired or wireless communication to the LAN 1152, which may also include a wireless access point disposed thereon for communicating with the wireless adaptor 1156. When used in a WAN networking environment, the computer 1102 can include a modem 1158, or is connected to a communications server on the LAN, or has other means for establishing communications over the WAN 1154, such as by way of the Internet. The modem 1158, which may be internal or external and a wired or wireless device, is connected to the system bus 1108 via the serial port interface 1142. In a networked environment, program modules depicted relative to the computer 1102, or portions thereof, may be stored in the remote memory/storage device 1150. It will be appreciated that the network connections shown are exemplary and other means of establishing a communications link between the computers may be used.

The computer 1102 is operable to communicate with any wireless devices or entities operably disposed in wireless communication, e.g., a printer, scanner, desktop and/or portable computer, portable data assistant, communications satellite, any piece of equipment or location associated with a wirelessly detectable tag (e.g., a kiosk, news stand, restroom), and telephone. This includes at least Wi-Fi and Bluetooth™ wireless technologies. Thus, the communication may be a predefined structure as with conventional network or simply an ad hoc communication between at least two devices.

Wi-Fi, or Wireless Fidelity, allows connection to the Internet from a couch at home, a bed in a hotel room or a conference room at work, without wires. Wi-Fi is a wireless technology like a cell phone that enables such devices, e.g., computers, to send and receive data indoors and out; anywhere within the range of a base station. Wi-Fi networks use radio technologies called IEEE 802.11 (a, b, g, etc.) to provide secure, reliable, fast wireless connectivity. A Wi-Fi network can be used to connect computers to each other, to the Internet, and to wired networks (which use IEEE 802.3 or Ethernet). Wi-Fi networks operate in the unlicensed 2.4 and 5 GHz radio bands, with an 11 Mbps (802.11b) or 54 Mbps (802.11a) data rate or with products that contain both bands (dual band), so the networks can provide real-world performance similar to the basic 10BaseT wired Ethernet networks used in many offices.

Although the invention has been shown and described with respect to a certain preferred embodiment or embodiments, it is obvious that equivalent alterations and modifications will occur to others skilled in the art upon the reading and understanding of this specification and the annexed drawings. In particular regard to the various functions performed by the above described components (assemblies, devices, circuits, etc.), the terms (including any reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more other features of the other embodiments as may be desired and advantageous for any given or particular application.

What is claimed is:

1. A system for controlling data retention in a memory cell comprising:
a memory cell comprising a memory storage medium, the memory storage medium comprising a controllably conductive media between a first electrode and at least a second electrode;
a first component that provides a programming signal to the memory cell; and
a second component that provides information to the first component based, at least in part, upon information associated with a measured current through the memory cell to controllably adjust the programming signal provided by the first component.

2. The system of claim 1, the information associated with the measured current through the memory device comprises an indication of when the current meets or exceeds a threshold level.

3. The system of claim 2, wherein the threshold current is associated with cell switching.

4. The system of claim 2, wherein the threshold current is associated with a programming state of the memory cell.

5. The system of claim 1, wherein the programming signal comprises a pulse magnitude and a pulse width.

6. The system of claim 5, wherein controllably adjusting the programming signal comprises reducing the pulse magnitude and controlling the pulse width.

7. The system of claim 1 wherein the second component controls the output of the first component.

8. The system of claim 5, upon detection of the measured current exceeding a threshold current level the first component provides a lower pulse magnitude.

9. The system of claim 1, wherein the controllably conductive media comprises:
a low conductive layer comprising at least one of an organic semiconductor material, an inorganic semiconductor material and a mixture of organic and inorganic semiconductor material; and
a passive layer comprising a conductivity facilitating compound.

10. A method of controlling data retention of a memory cell, comprising:
measuring a current applied to at least one memory cell, the memory cell having a controllably conductive media between a first electrode and at least a second electrode;
generating data related to the measured current; and
employing the data to control a program operation of the at least one memory cell via an external stimuli.

11. The method of claim 10, wherein generating data comprises creating a signal based upon a relation between the measured current and a predetermined current level.

12. The method of claim 11, wherein the signal is generated when the measured current reaches or exceeds the predetermined current level.

13. The method of claim 10, wherein employing the data further comprises adjusting the external stimuli.

14. The method of claim 10, wherein the external stimuli comprises a pulse magnitude and a pulse width.

15. The method of claim 14, wherein adjusting the external stimuli further comprises reducing the pulse magnitude.

16. The method of claim 14, wherein adjusting the external stimuli further comprises controlling the pulse width.

17. The method of claim 10, wherein the external stimuli is a waveform.

18. The method of claim 17, wherein the waveform is a staircase pulse.

19. The method of claim 11, wherein the predetermined current level comprises a program state of the memory cell.

20. The method of claim 11, wherein the predetermined current level indicates cell switching.

21. The method of claim 10, wherein the controllably conductive media comprises:
a low conductive layer comprising at least one of an organic semiconductor material, an inorganic semiconductor material and a mixture of organic and inorganic semiconductor material; and
a passive layer comprising a conductivity facilitating compound.

22. A system for controlling data in a memory cell comprising:
means for providing an input signal to the memory cell;
means for monitoring the programming state of the memory cell;
means for adjusting the input signal based upon the programming state of the memory cell.
